(19) United States
(12) Patent Application Publication
(10) Pub. No.: US 2013/0320479 A1
(43) Pub. Date: Dec. 5, 2013

(54) IMAGE SENSOR, IMAGE PROCESSING SYSTEM INCLUDING THE IMAGE SENSOR, AND METHOD OF MANUFACTURING THE IMAGE SENSOR

(71) Applicant: SAMSUNG ELECTRONICS CO., LTD., Suwon-si (KR)

(72) Inventors: Jung Chak AHN, Yongin-si (KR); Kyung Ho LEE, Bucheon-si (KR); Sang Jun CHOI, Yongin-si (KR)

(73) Assignee: SAMSUNG ELECTRONICS CO., LTD., Suwon-si (KR)

(21) Appl. No.: 13/836,226

(22) Filed: Mar. 15, 2013

(30) Foreign Application Priority Data
May 30, 2012 (KR) 10-2012-0057713

(51) Int. Cl. H01L 31/02; H01L 31/18

(52) U.S. Cl. CPC H01L 31/02; H01L 31/18
USPC 257/460; 438/57

(57) ABSTRACT

An image sensor includes a photodetector formed in an epitaxial layer, and trench isolations each formed in a direction from a back side of the epitaxial layer to a front side of the epitaxial layer. Each of the trench isolations is filled with at least one insulator, and the insulator is a negative charge material.

### CROSS-REFERENCE TO RELATED APPLICATIONS

This application claims priority under 35 U.S.C. §119 from Korean Patent Application No. 10-2012-0057713, filed on May 30, 2012, in the Korean Intellectual Property Office, the disclosure of which is incorporated herein in its entirety by reference.

### BACKGROUND OF THE INVENTION

1. Field of the Invention

Example embodiments relate to a back side illuminated (BSI) image sensor, and more particularly, to an image sensor that uses one or more trench isolations to reduce crosstalk, an image processing system including the image sensor, and a method of manufacturing the image sensor.

2. Description of the Related Art

A BSI image sensor converts an optical image into an electrical image. The BSI image sensor has a different arrangement from a conventional image sensor in order to increase the amount of captured light.

As the size of the BSI image sensor decreases, crosstalk may occur in the BSI image sensor. The crosstalk may be an optical crosstalk in which incident light received via a color filter is transmitted to an adjacent photodetector adjacent or electrical crosstalk in which an electron-hole pair generated in a depletion region of a photodetector is transmitted to an adjacent photodetector. The crosstalk may cause image distortion.

### SUMMARY OF THE INVENTION

The present general inventive concept provides an image sensor having a structure to reduce crosstalk, an electronic apparatus having the image sensor, and a method thereof.

Additional features and utilities of the present general inventive concept will be set forth in part in the description which follows and, in part, will be obvious from the description, or may be learned by practice of the general inventive concept

The forgoing and/or other features and utilities of the present general inventive concept may be achieved by providing an image sensor including a photodetector formed in an epitaxial layer, and trench isolations each formed in a direction from a back side of the epitaxial layer to a front side of the epitaxial layer. Each of the trench isolations may be filled with at least one insulator, and the insulator may be a negative charge material. A depth of each of the trench isolations may be equal to a depth of the epitaxial layer. The negative charge material may be hypofluorous acid. The photodetector may be formed between the trench isolations.

The forgoing and/or other features and utilities of the present general inventive concept may also be achieved by providing an image processing system comprising the above-described image sensor; and a processor which processes a signal output by the image sensor. The image processing system is a mobile device.

The forgoing and/or other features and utilities of the present general inventive concept may also be achieved by providing a method of manufacturing an image sensor, the method including forming each of trench isolations in a direction from a back side of an epitaxial layer to a front side of the epitaxial layer; and forming a photodetector in the epitaxial layer.

The method may further include filling the trench isolations with at least one insulator. The insulator may be oxide or a negative charge material. The negative charge material may be hypofluorous acid.

The forgoing and/or other features and utilities of the present general inventive concept may also be achieved by providing an image sensor usable with an electronic apparatus, including an epitaxial layer including a photodetector and a plurality of trench isolations disposed adjacent to the photodetector.

The image sensor may further include a filter disposed over a back side of the epitaxial layer, a lens disposed on the filter, and a substrate disposed over a front side of the epitaxial layer. The trench isolation may be formed in a direction from the back side toward the front side and may be oxide or a negative charge material.

The trench isolations may be arranged in the epitaxial layer and have a thickness variable according to a distance from the back side or the front side of the epitaxial layer.

The trench isolations may have a same length in a direction from the back side toward the front side.

At least one of the trench isolations may have a length different from the other one of the trench isolations.

The photodetector may have a height from a front side of the epitaxial layer, and the trench isolations may be extended from a back side of the epitaxial layer by a length longer than the height of the photodetector.

At least a portion of the trench isolations may be disposed between the adjacent photodetectors.

The trench isolations each may include a first isolation layer extended from a back side of the epitaxial layer toward a front side of the epitaxial layer and having a variable thickness, and a second isolation layer disposed on the first isolation layer.

The electronic apparatus may be an image processing system to process an image formed from the above described image sensor.

### BRIEF DESCRIPTION OF THE DRAWINGS

These and/or other features and utilities of the present general inventive concept will become apparent and more readily appreciated from the following description of the embodiments, taken in conjunction with the accompanying drawings of which:

FIG. 1 is a cross-sectional view illustrating a pixel region usable with a sensor according to an embodiment of the inventive concept;

FIG. 2 is a cross-sectional view illustrating a pixel region usable with a sensor according to an embodiment of the inventive concept;

FIG. 3 is a cross-sectional view illustrating a pixel region usable with a sensor according to an embodiment of the inventive concept;

FIG. 4 is a cross-sectional view illustrating a pixel region usable with a sensor according to an embodiment of the inventive concept;

FIG. 5 is a diagram illustrating a method of manufacturing an image sensor according to an embodiment of the invention concept;

FIGS. 6 through 8 are cross-sectional views illustrating a method of manufacturing an image sensor according to an embodiment of the invention concept;

FIG. 9 is a flowchart illustrating a method of manufacturing an image sensor according to an embodiment of the invention concept;

FIG. 10 is a block diagram illustrating an image sensor including a pixel region according to an embodiment of the inventive concept;

FIG. 11 is a block diagram illustrating an image processing system including the image sensor illustrated in FIG. 10 according to an embodiment of the present general inventive concept; and

FIG. 12 is a block diagram illustrating an image processing system including the image sensor illustrated in FIG. 10 according to an embodiment of the present general inventive concept.

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to the like elements throughout. The embodiments are described below in order to explain the present general inventive concept while referring to the figures.

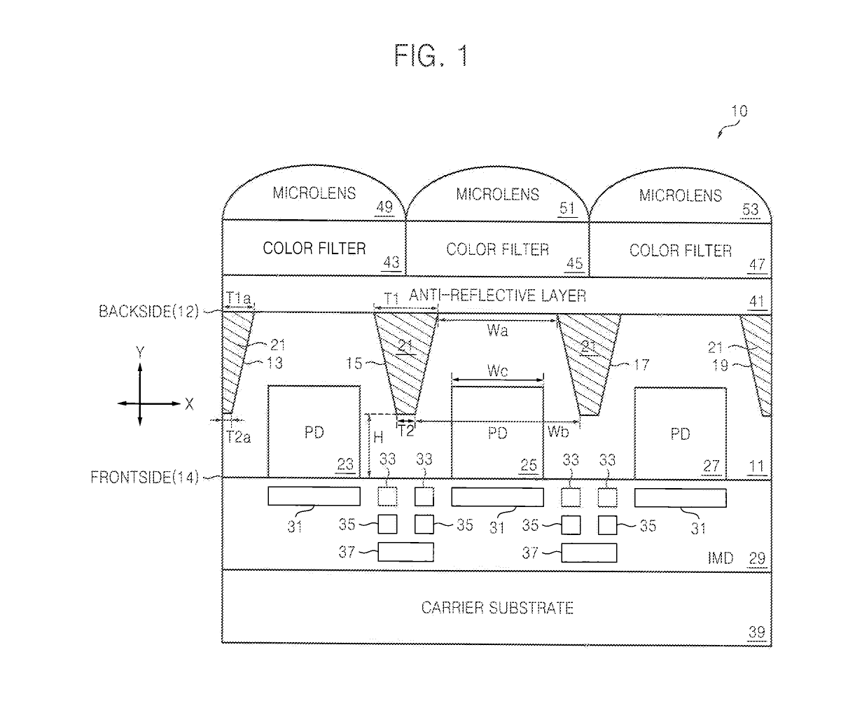

FIG. 1 is a cross-sectional view illustrating a pixel region 10 usable with a sensor, for example, an image sensor, according to an embodiment of the inventive concept. Referring to FIG. 1, the pixel region 10 includes an epitaxial layer 11, an inter-metal dielectric layer 29, a carrier substrate 39, an anti-reflective layer 41, color filters 43, 45, and 47, and microlenses 49, 51, and 53.

Trench isolations 13, 15, 17, and 19 are formed in a direction from a back side 12 of the epitaxial layer 11 to a front side 14 of the epitaxial layer 11. Due to the formation of the trench isolations 13, 15, 17, and 19, optical crosstalk and electrical crosstalk may be reduced. Each of the trench isolations 13, 15, 17, and 19 may be filled with an insulator 21. For example, the insulator 21 may be oxide.

Each of the photodetectors 23, 25, and 27 may generate a photoelectron in response to light incident from an external source. The photodetectors 23, 25, and 27 are formed in the epitaxial layer 11. Each of the photodetectors 23, 25, and 27 is a photosensitive element and may be implemented by using a photodiode, a phototransistor, a photogate, or a pinned photodiode (PPD).

The inter-metal dielectric layer 29 may be formed of an oxide layer, or a composite layer of an oxide layer and a nitride layer. The oxide layer may be a silicon oxide layer. The inter-metal dielectric layer 29 may include metal elements 31, 33, 35, and 37. Electrical wiring necessary for a sensing operation of the pixel region 10 may be formed by the metal elements 31, 33, 35, and 37. According to an embodiment, the metal element 31 may be usable to reflect light received via the photodetector 23, 25 or 27 back to the corresponding photodetector 23, 25 or 27. The metal elements 31, 33, 35, and 37 may be copper, titanium, or titanium nitride. The carrier substrate 39 may be a silicon substrate. The anti-reflective layer 41 is used to reduce reflection. The anti-reflective layer 41 improves a contrast of an image.

Each of the color filters 43, 45, and 47 transmits light having wavelengths in a visible region. For example, the color filter 43, 45 or 47 may be a red filter, a green filter, or a blue filter. The red filter transmits wavelengths in a red region from among the wavelengths in the visible region. The green filter transmits wavelengths in a green region from among the wavelengths in the visible region. The blue filter transmits wavelengths in a blue region from among the wavelengths in the visible region.

According to an embodiment, the color filter 43, 45 or 47 may be a cyan filter, a magenta filter, or a yellow filter. The cyan filter transmits wavelengths in a 450-550 nm region from among the wavelengths in the visible region. The magenta filter transmits wavelengths in a 400-480 nm region from among the wavelengths in the visible region. The yellow filter transmits wavelengths in a 500-600 nm region from among the wavelengths in the visible region. Each of the microlenses 49, 51, and 53 concentrates light incident from an external source. According to an embodiment, the pixel region 10 may be implemented without including the microlenses 49, 51, and 53.

The insulator 21 may have a first thickness T1 and a second thickness T2 in a direction X which are variable according to a distance in a direction Y from the front side 14 or the back side 12 of the epitaxial layer 11. The insulator 21 may have a first sub-thickness T1a and a second sub-thickness T2a which are variable according to a distance in a direction Y from the front side 14 or the back side 12 of the epitaxial layer 11.

The adjacent insulators 21 may be spaces apart by a first width Wa and a second width Wb in the X direction which are variable according to a distance in a direction Y from the front side 14 or the back side 12 of the epitaxial layer 11. A width We of the photodetector 23, 25, or 27 may be substantially same as or narrower than at least one of the widths Wa and Wb.

The insulator 21 may be spaced apart from the front side 14 by a height H. The insulator 21 may have a distal end disposed between the adjacent photodetectors 23, 25, and 27.

The photodetector 23, 25, and 27 may have a height higher than a half of a height of the the epitaxial layer 11 in the direction Y.

Although FIG. 1 illustrates a distal end of the insulator 21 to have a flat surface parallel to a major surface of the front side 14, the present general inventive concept is not limited thereto. It is possible that the distal end of the insulator 21 may be a curved surface, for example, a convex surface or a concave surface. It is also possible that the distal end of the insulator 21 may have a surface with a predetermined roughness.

Although FIG. 1 illustrates the insulators 21 having the same length L in a height direction from the back side 12 toward front side 14, at least one of the insulators 21 may have a different length L from the other one of the insulators 21 in the height direction. For example, at least one of the insulators 21 disposed on edge sides of the epitaxial layer 11 may have a length L in the height direction to be longer than that of the other one disposed in a middle portion of the epitaxial layer 11 between the edge sides of the epitaxial layer 11.

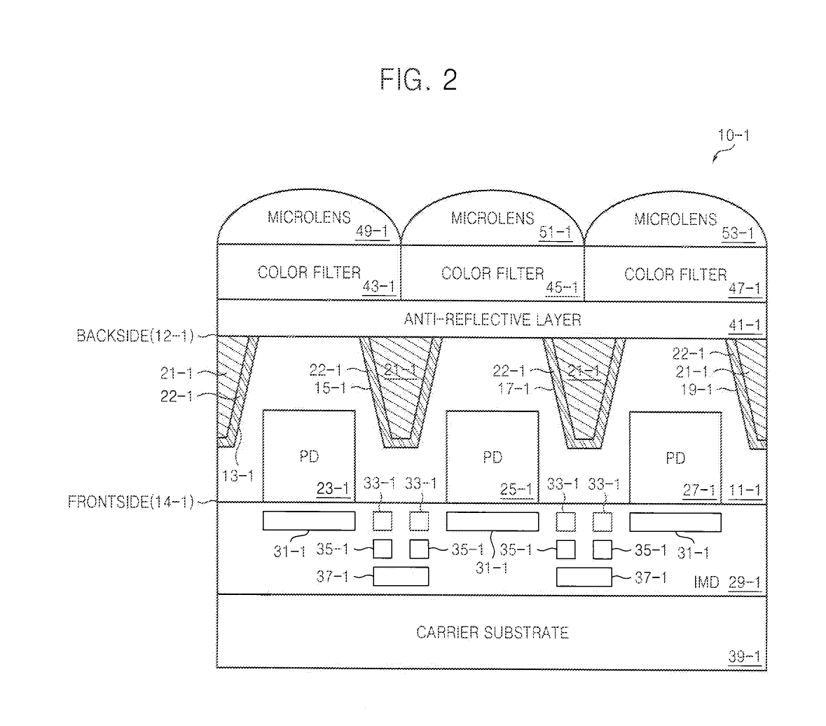

FIG. 2 is a cross-sectional view illustrating a pixel region 10-1 usable with a sensor, for example, an image sensor according to an embodiment of the inventive concept. Referring to FIG. 2, the pixel region 10-1 includes an epitaxial layer 11-1, an inter-metal dielectric layer 29-1, a carrier substrate 39-1, an anti-reflective layer 41-1, color filters 43-1, 45-1, and 47-1, and microlenses 49-1, 51-1, and 53-1.

Trench isolations 13-1, 15-1, 17-1, and 19-1 are formed in a direction from a back side 12-1 of the epitaxial layer 11-1 to a front side 14-1 of the epitaxial layer 11-1. Each of the trench isolations 13-1, 15-1, 17-1, and 19-1 may be filled with at least one insulator. Each of the trench isolations 13-1, 15-1, 17-1, and 19-1 may be filled with a first insulator 21-1 and a second insulator 22-1. For example, the first insulator 21-1 may be oxide, and the second insulator 22-1 may be a negative charge material. For example, the negative charge material may be hypofluorous acid.

The first insulators 21-1 may be thicker than the second insulators 22-1. It is possible that at least a portion of the first insulator 21-1 may have a thickness to be same as or narrower than a thickness of the second insulator 22-1.

Since the functions of the components 11-1, 23-1, 25-1, 27-1, 29-1, 39-1, 41-1, 43-1, 45-1, 47-1, 49-1, 51-1, and 53-1 of FIG. 2 are similar to those of the components 11, 23, 25, 27, 29, 39, 41, 43, 45, 47, 49, 51, and 53 of FIG. 1, respectively, a detailed description thereof will be omitted.

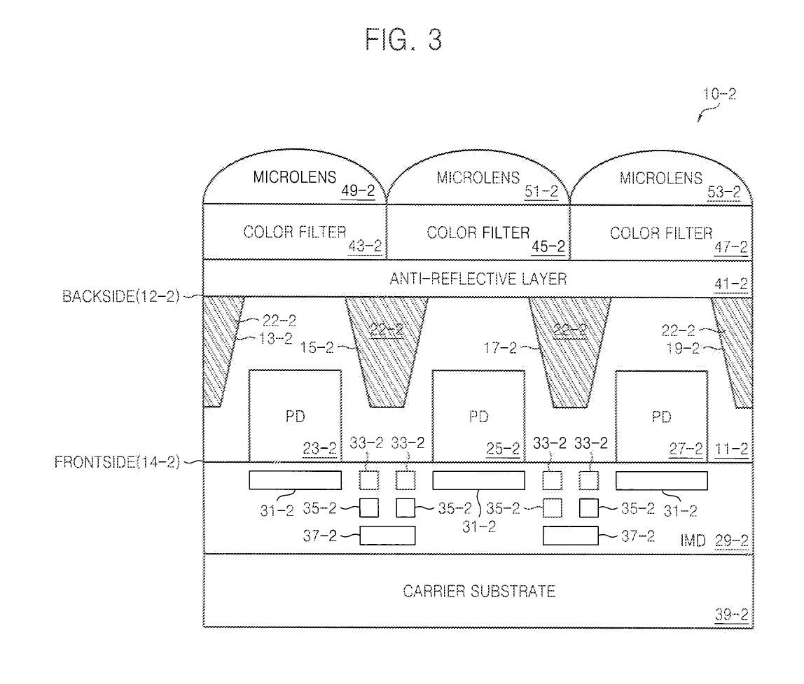

FIG. 3 is a cross-sectional view illustrating a pixel region 10-2 according to an embodiment of the inventive concept. Referring to FIG. 3, the pixel region 10-2 includes an epitaxial layer 11-2, an inter-metal dielectric layer 29-2, a carrier substrate 39-2, an anti-reflective layer 41-2, color filters 43-2, 45-2, and 47-2, and microlenses 49-2, 51-2, and 53-2.

Trench isolations 13-2, 15-2, 17-2, and 19-2 are formed in a direction from a back side 12-2 of the epitaxial layer 11-2 to a front side 14-2 of the epitaxial layer 11-2. Each of the trench isolations 13-2, 15-2, 17-2, and 19-2 may be filled with an insulator 22-2. For example, the insulator 22-2 may be a negative charge material. The negative charge material may be hypofluorous acid. When each of the trench isolations 13-2, 15-2, 17-2, and 19-2 is filled with a negative charge material, each of the trench isolations 13-2, 15-2, 17-2, and 19-2 accumulates holes on its surface, thereby preventing generation of a dark current. When the epitaxial layer 11-2 is etched to form the trench isolations 13-2, 15-2, 17-2, and 19-2, a surface of the trench isolation 13-2, 15-2 17-2 or 19-2 may be damaged, and thus a dark current causing a dark portion to an image may be generated due to the damage.

Since the functions of the components 11-2, 23-2, 25-2, 27-2, 29-2, 39-2, 41-2, 43-2, 45-2, 47-2, 49-2, 51-2, and 53-2 of FIG. 3 are similar to those of the components 11, 23, 25, 27, 29, 39, 41, 43, 45, 47, 49, 51, and 53 of FIG. 1, respectively, a detailed description thereof will be omitted.

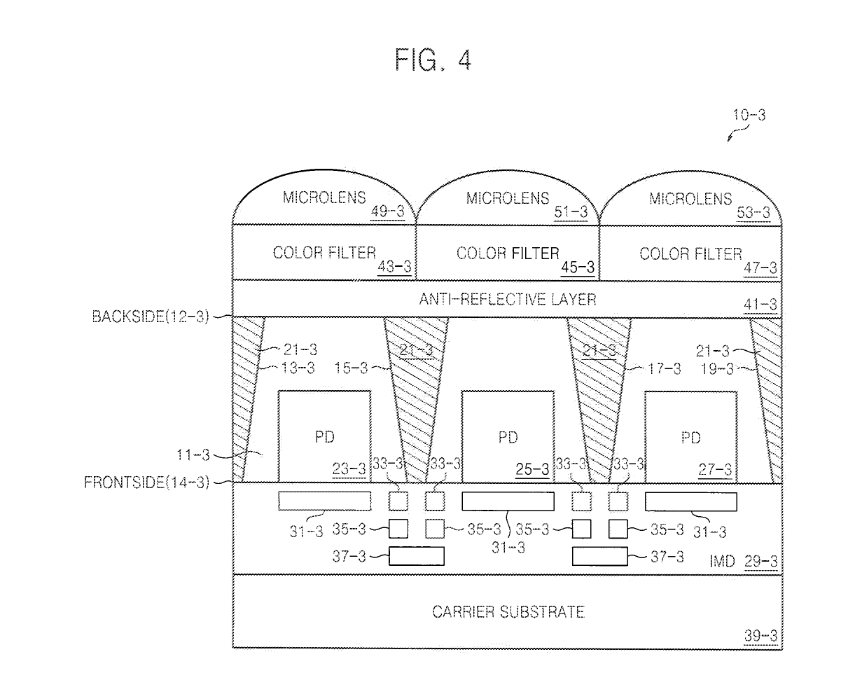

FIG. 4 is a cross-sectional view illustrating a pixel region 10-3 according to an embodiment of the inventive concept. Referring to FIG. 4, the pixel region 10-3 includes an epitaxial layer 11-3, an inter-metal dielectric layer 29-3, a carrier substrate 39-3, an anti-reflective layer 41-3, color filters 43-3, 45-3, and 47-3, and microlenses 49-3, 51-3, and 53-3.

Trench isolations 13-3, 15-3, 17-3, and 19-3 are formed in a direction from a back side 12-3 of the epitaxial layer 11-3 to a front side 14-3 of the epitaxial layer 11-3. The depth of each of the trench isolations 13-3, 15-3, 17-3, and 19-3 is equal to that of the epitaxial layer 11-3. The trench isolations 13-3, 15-3, 17-3, and 19-3 may be formed more deeply than the trench isolations 13-2, 15-2, 17-2, and 19-2 illustrated in FIG. 3 in order to more efficiently reduce optical crosstalk and electrical crosstalk.

Each of the trench isolations 13-3, 15-3, 17-3, and 19 may be filled with at least one insulator 21-3. For example, the insulator 21-3 may be oxide. According to an embodiment, the insulator 21-3 may be a negative charge material. The negative charge material may be hypofluorous acid. However, the present general inventive concept is not limited thereto. It is possible that the insulator 21-3 may be oxide and hypofluorous acid.

Since the functions of the components 11-3, 23-3, 25-3, 27-3, 29-3, 39-3, 41-3, 43-3, 45-3, 47-3, 49-3, 51-3, and 53-3 of FIG. 4 are similar to those of the components 11, 23, 25, 27, 29, 39, 41, 43, 45, 47, 49, 51, and 53 of FIG. 1, respectively, a detailed description thereof will be omitted.

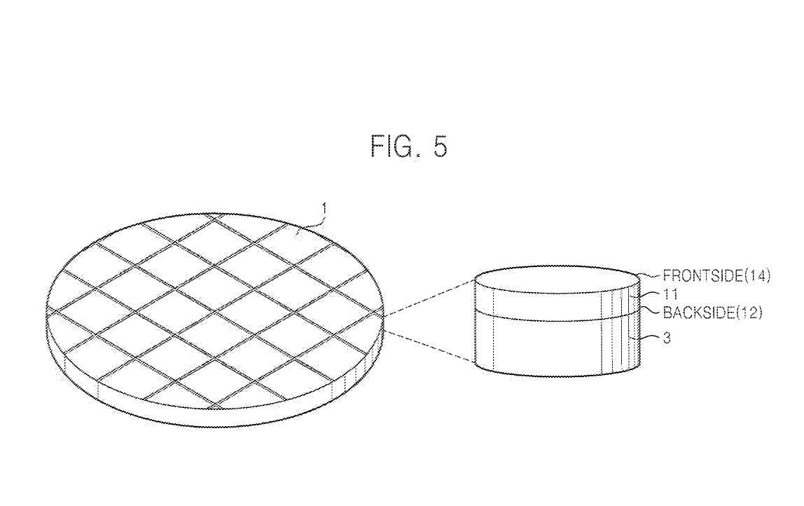

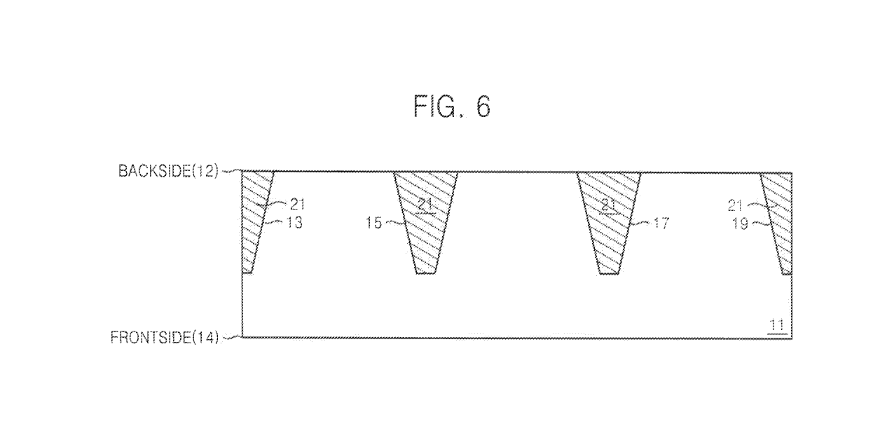

FIG. 5 is a diagram illustrating a method manufacturing an image sensor according to an embodiment of the invention concept. FIGS. 6 through 8 are cross-sectional views illustrating a method of manufacturing the image sensor illustrated in FIG. 1. Referring to FIGS. 1 and 5, a wafer 1 includes a substrate 3 and the epitaxial layer 11 disposed on the substrate 3. The epitaxial layer 11 is formed by dropping silicon atoms onto a heated wafer 1. After the epitaxial layer 11 is formed, the substrate 3 may be removed. The epitaxial layer 11 may include the back side 12 and the front side 14.

Referring to FIG. 6, the epitaxial layer 11 is etched to form the trench isolations 13, 15, 17, and 19. The trench isolations 13, 15, 17, and 19 are formed in the direction from the back side 12 of the epitaxial layer 11 to the front side 14 of the epitaxial layer 11.

Each of the trench isolations 13, 15, 17, and 19 may be filled with at least one insulator 21. For example, the insulator 21 may be oxide or a negative charge material. The negative charge material may be hypofluorous acid. According to an embodiment, the trench isolations 13, 15, 17, and 19 may be filled with oxide and a negative charge material. The trench isolations 13, 15, 17, and 19 may be more easily filled with the negative charge material when they are formed on the back side 12 than when they are formed on the front side 14.

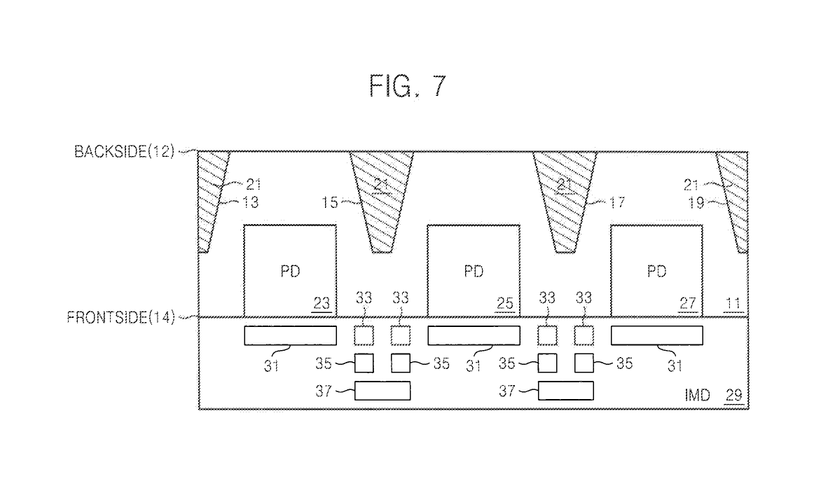

Referring to FIG. 7, after the trench isolations 13, 15, 17, and 19 are formed in the epitaxial layer 11, the photodetectors 23, 25, and 27 are formed in the epitaxial layer 11. The photodetector 23 is formed between the trench isolations 13 and 15, the photodetector 25 is formed between the trench isolations 15 and 17, and the photodetector 27 is formed between the trench isolations 17 and 19. Due to the formation of the trench isolations 13, 15, 17, and 19, optical crosstalk or electrical crosstalk may be reduced.

The inter-metal dielectric layer 29 is disposed on the front side 14 of the epitaxial layer 11. The inter-metal dielectric layer 29 includes the metals 31, 33, 35, and 37.

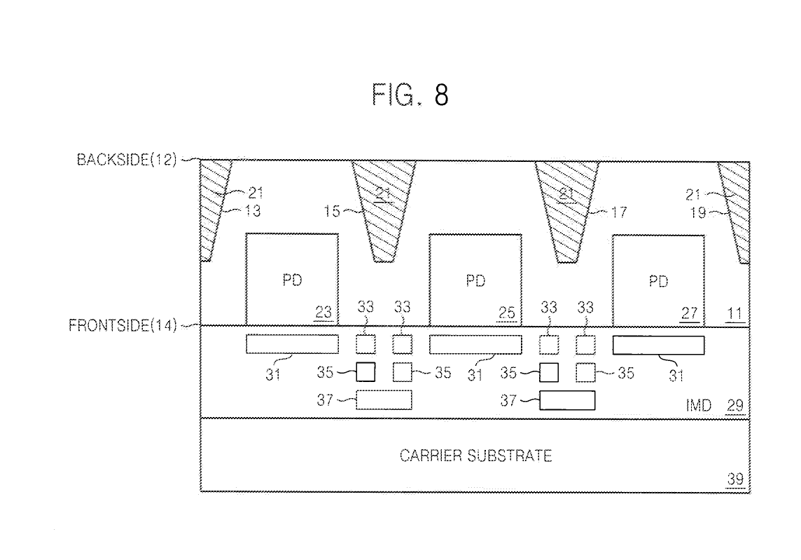

Referring to FIGS. 1 and 8, the carrier substrate 39 is disposed on the inter-metal dielectric layer 29. Thereafter, the anti-reflective layer 41, the color filters 43, 45, and 47, and the microlenses 49, 51, and 53 are disposed on the back side 12 of the epitaxial layer 11.

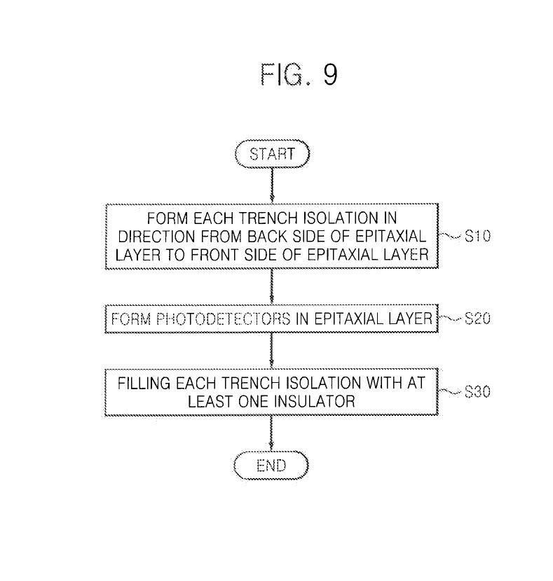

FIG. 9 is a flowchart illustrating a method of manufacturing the image sensor illustrated in FIG. 1 according to an embodiment of the present general inventive concept. Referring to FIGS. 1 and 5-9, the epitaxial layer 11 is etched to form the trench isolations 13, 15, 17, and 19, in operation S10. The trench isolations 13, 15, 17, and 19 are formed in the direction from the back side 12 of the epitaxial layer 11 to the front side 14 of the epitaxial layer 11.

After the trench isolations 13, 15, 17, and 19 are formed in the epitaxial layer 11, the photodetectors 23, 25, and 27 are formed in the epitaxial layer 11, in operation S20. The photodetector 23 is formed between the trench isolations 13 and 15, the photodetector 25 is formed between the trench isolations 15 and 17, and the photodetector 27 is formed between the trench isolations 17 and 19. Each of the trench isolations 13, 15, 17, and 19 may be filled with the at least one insulator 21, in operation S30. Due to the formation of the trench isolations 13, 15, 17, and 19, optical crosstalk or electrical crosstalk may be reduced.

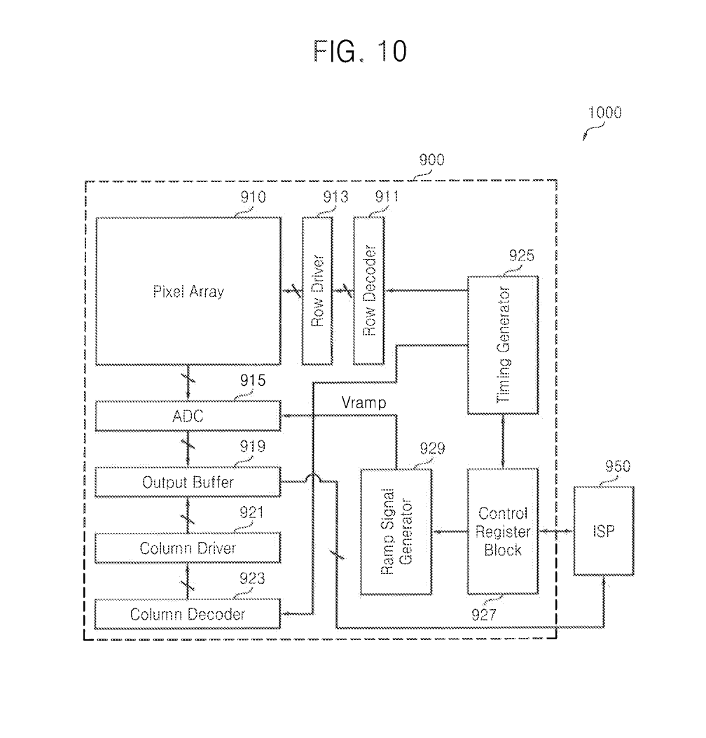

FIG. 10 is a block diagram illustrating an image sensor 1000 including pixels according to an embodiment of the inventive concept. Referring to FIG. 10, the image sensor 1000 includes a photoelectric conversion circuit 900 and an image signal processor (ISP) 950. Each of the photoelectric conversion circuit 900 and the ISP 950 may be implemented by using a separate chip, or both of the photoelectric conversion circuit 900 and the ISP 950 may be implemented by using a single chip.

The photoelectric conversion circuit 900 may generate an image signal corresponding to an object in response to incident light. The photoelectric conversion circuit 900 may include a pixel array 910, a row decoder 911, a row driver 913, an analog-to-digital converter (ADC) 915, an output buffer 919, a column driver 921, a column decoder 923, a timing generator 925, a control register block 927, and a ramp signal generator 929.

The pixel array 910 may include the pixel region 10, 10-1, 10-2, or 10-3 of FIG. 1, 2, 3, or 4 and has a matrix shape in which the pixel region 10, 10-1, 10-2, or 10-3 is connected to a plurality of row lines and a plurality of column lines.

The row decoder 911 may decode a row control signal (for example, an address signal) generated by the timing generator 925, and the row driver 913 may select at least one from the row lines of the pixel array 910, in response to the decoded row control signal. The ADC 915 compares a pixel signal output by each of unit pixels connected to the column lines that comprise the pixel array 910 with a ramp signal Vramp and outputs a digital signal according to a result of the comparison.

The output buffer 919 buffers and outputs the digital signal output by the ADC 915, in response to a column control signal (for example, an address signal) output by the column driver 921. The column driver 921 may activate at least one of the column lines of the pixel array 910, in response to a decoded control signal (for example, an address signal) output by the column decoder 923. The column decoder 923 may decode a control signal (for example, an address signal) generated by the timing generator 925.

The timing generator 925 may generate a control signal for controlling an operation of at least one of the pixel array 910, the row decoder 911, and the column decoder 923, based on a command output by the control register block 927. The control register block 927 may generate a variety of commands for controlling components that comprise the photoelectric conversion circuit 900.

The ramp signal generator 929 may output the ramp signal Vramp to the ADC 915 in response to a command output by the control register block 927. The ISP 950 may generate an image corresponding to the subject, based on pixel signals output by the photoelectric conversion circuit 900.

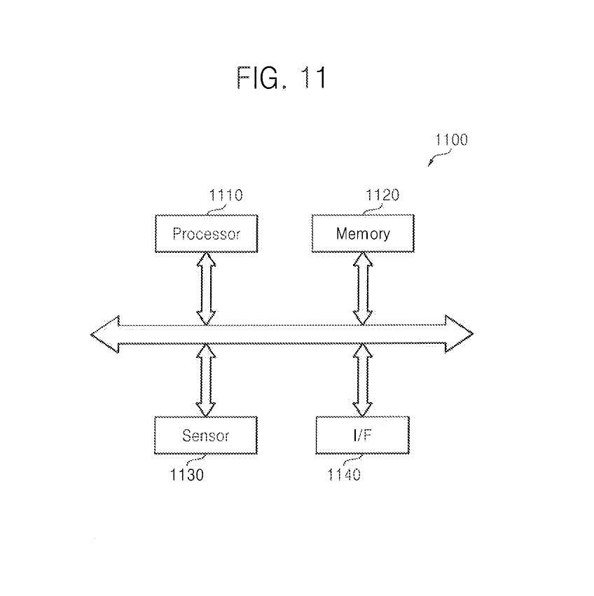

FIG. 11 is a block diagram illustrating an image processing system 1100 including the image sensor 1000 of FIG. 10 according to an embodiment of the present general inventive concept. Referring to FIG. 11, the image processing system 1100 may include a digital camera, a mobile phone having a digital camera built therein, or any electronic device including a digital camera. The image processing system 1100 may process two-dimensional or three-dimensional image information. The image processing system 1100 may include an image sensor 1130 and a processor 1110 to control operations of the image sensor 1130. The image sensor 1130 denotes the image sensor 1000 of FIG. 10.

According to an embodiment, the image processing system 1100 may further include an interface (I/F) 1140. The I/F 1140 may be an image display such as a display.

According to an embodiment, the image processing system 1100 may further include a memory device 1120 capable of storing still images or moving pictures captured by the image sensor 1130. The memory device 1120 may be configured as a non-volatile memory device. The non-volatile memory device may be configured as an electrically erasable programmable read-only Memory (EEPROM), a flash memory, a magnetic RAM (MRAM), a spin-transfer torque MRAM (STT-MRAM), a conductive bridging RAM (CBRAM), a ferroelectric RAM (FeRAM), a phase change RAM (PRAM) which is also called an ovonic unified memory (OUM), a resistive RAM (RRAM or ReRAM), a nanotube RRAM, a polymer RAM (PoRAM), a nano floating gate memory (NFGM), a holographic memory, a molecular electronics memory device, an insulator resistance change memory, or the like.

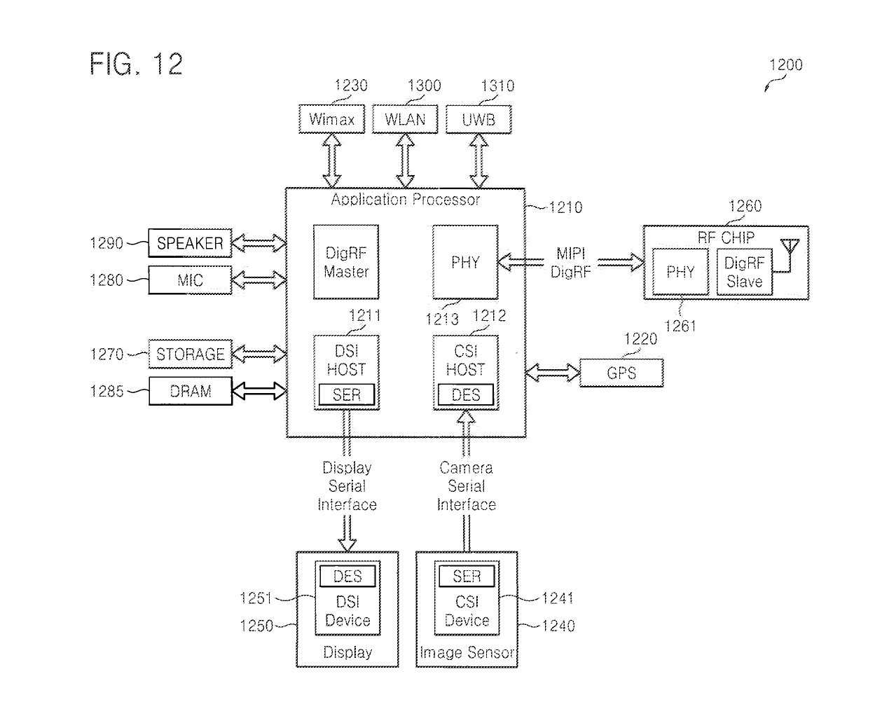

FIG. 12 is a block diagram illustrating an image processing system 1200 including the image sensor 1000 of FIG. 10 according to an embodiment of the present general inventive concept. Referring to FIG. 12, the image processing system 1200 may be implemented by using a data processing device capable of using or supporting a mobile industry processor interface (MIPI) interface, for example, a mobile phone, a personal digital assistant (PDA), a portable multi-media player (PMP), or a smart phone.

The image processing system 1200 includes an application processor 1210, an image sensor 1240, and a display 1250.

A camera serial interface (CSI) host 1212 implemented in the application processor 1210 may serially communicate with a CSI device 1241 of the image sensor 1240 via a CSI. In this case, for example, an optical deserializer DES may be implemented in the CSI host 1212, and an optical serializer SER may be implemented in the CSI device 1241. The image sensor 1240 denotes the image sensor 1000 of FIG. 10.

A display serial interface (DSI) host 1211 implemented in the application processor 1210 may serially communicate with a DSI device 1251 of the display 1250 via a DSI. In this case, for example, an optical serializer SER may be implemented in the DSI host 1211, and an optical deserializer DES may be implemented in the DSI device 1251.

The image processing system 1200 may further include a radio frequency (RF) chip 1260 capable of communicating with the application processor 1210. A physical layer (PHY) 1213 of the application processor 1210 and a PHY 1261 of the RF chip 1260 may transmit and receive data to and from each other via MIPI DigRF.

The image processing system 1200 may further include a global positioning system (GPS) 1220, a storage 1270, a microphone (MIC) 1280, a DRAM 1285, and a speaker 1290, and may communicate with other system via Wimax 1230, a Wireless Local Area Network (WLAN) 1300, and a Ultra-WideBand (UWB) 1310.

In an image sensor capable of reducing crosstalk according to the inventive concept, an image processing system including the image sensor, and a method of manufacturing the image sensor, trench isolations are formed, and thus crosstalk may be reduced.

Moreover, in the image sensor capable of reducing crosstalk according to the inventive concept, the image processing system including the image sensor, and the method of manufacturing the image sensor, the trench isolations are filled with a negative charge material, and thus noise which is generated by a dark current may be reduced.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. An image sensor comprising:
a photodetector formed in an epitaxial layer; and
trench isolations each formed in a direction from a back side of the epitaxial layer to a front side of the epitaxial layer,
wherein each of the trench isolations is filled with at least one insulator, and the insulator is a negative charge material.

2. The image sensor of claim 1, wherein a depth of each of the trench isolations is equal to a depth of the epitaxial layer.

3. The image sensor of claim 1, wherein the negative charge material is hypofluorous acid.

4. The image sensor of claim 1, wherein the photodetector is formed between the trench isolations.

5. An image processing system comprising:
the image sensor of claim 1; and
a processor which processes a signal output by the image sensor.

6. The image processing system of claim 5, wherein the image processing system is a mobile device.

7. A method of manufacturing an image sensor, the method comprising:
forming each of trench isolations in a direction from a back side of an epitaxial layer to a front side of the epitaxial layer; and
forming a photodetector in the epitaxial layer.

8. The method of claim 7, further comprising:
filling the trench isolations with at least one insulator.

9. The method of claim 8, wherein the insulator is oxide or a negative charge material.

10. The method of claim 9, wherein the negative charge material is hypofluorous acid.

11. The method of claim 7, wherein the photodetector is formed between the trench isolations.

12. The image sensor of claim 1, wherein the trench isolations are arranged in the epitaxial layer and have a thickness variable according to a distance from the back side or the front side of the epitaxial layer.

13. The image sensor of claim 1, wherein the photodetector has a height from a front side of the epitaxial layer, and the trench isolations are extended from a back side of the epitaxial layer by a length longer than the height of the photodetector.
